(19) United States
(12) Patent Application Publication
(10) Pub. No.: US 2024/0147744 A1
(43) Pub. Date: May 2, 2024

(54) SENSOR-EMBEDDED DISPLAY PANEL AND SENSOR AND ELECTRONIC DEVICE

(71) Applicant: Samsung Electronics Co., Ltd., Suwon-si (KR)

(72) Inventors: Sungyoung YUN, Suwon-si (KR); Hyeong-Ju KIM, Suwon-si (KR); Kyung Bae PARK, Suwon-si (KR); Jungyun WON, Suwon-si (KR); Bongsu KIM, Suwon-si (KR); Seongyong PARK, Suwon-si (KR); Jeong Il PARK, Suwon-si (KR)

(73) Assignee: Samsung Electronics Co., Ltd., Suwon-si (KR)

(21) Appl. No.: 18/472,930

(22) Filed: Sep. 22, 2023

(30) Foreign Application Priority Data
Oct. 28, 2022 (KR) 10-2022-0141511

(51) Int. Cl. H10K 39/34; H10K 59/35

(52) U.S. Cl. CPC H10K 39/34; H10K 59/353; H10K 2101/40

(57) ABSTRACT

A display panel may include a light emitting element including a light emitting layer and a sensor including a photosensitive layer on a substrate. The light emitting element and the sensor each may include respective portions of first and second common auxiliary layers, which may be continuous under and over the light emitting layer and the photosensitive layer. The first and second common auxiliary layers respectively may include a hole transport material and an electron transport material. The photosensitive layer may include first and second semiconductor layers close to the first and second common auxiliary layers, respectively. The first and second semiconductor layers respectively may include a p-type semiconductor and an n-type semiconductor. The second semiconductor layer may have an uneven surface facing the second common auxiliary layer and may have an average roughness (Rq) of greater than or equal to about 5 nm.

### CROSS-REFERENCE TO RELATED APPLICATION

This application claims priority to and the benefit of Korean Patent Application No. 10-2022-0141511 filed in the Korean Intellectual Property Office on Oct. 28, 2022, the entire contents of which are incorporated herein by reference.

### BACKGROUND

### 1. Field

A sensor-embedded display panel, a sensor, and an electronic device are disclosed.

### 2. Description of the Related Art

Recently, there is an increasing demand for a display device implementing a biometric recognition technology that authenticates the person by extracting specific biometric information or behavioral characteristic information of a person with an automated device centering on finance, healthcare, and mobile. Accordingly, the display device may include a sensor for biometric recognition.

### SUMMARY

A sensor for biometric recognition may be divided into an electrostatic type, an ultrasonic type, or an optical type. Among them, the optical type sensor is a sensor configured to absorb light and convert the absorbed light into an electrical signal. An organic material may have a large extinction coefficient and may be configured to selectively absorb light in a specific wavelength region according to a molecular structure, and thus it may be usefully applied to an optical type sensor.

On the other hand, the sensor provided in the display device may be disposed under the display panel or may be manufactured as a separate module and mounted outside of the display panel. However, when the sensor is disposed under the display panel, the object should be recognized through the display panel, various films, and/or parts, and thus performance may be degraded. When the sensor is manufactured and mounted as a separate module, there are limitations in terms of design and usability. Accordingly, an approach to embed a sensor in the display panel may be considered. However, since the performance and physical properties required for the sensor may be different from those required for the display panel, it may be difficult to implement in an integrated form.

Some example embodiments provide a sensor-embedded display panel including a sensor capable of improving performance by being integrated with the display panel.

Some example embodiments provide an electronic device including the sensor-embedded display panel.

According to an example embodiment, a sensor-embedded display panel may include a substrate; a light emitting element on the substrate, the light emitting element including a light emitting layer; and a sensor on a substrate, the sensor including a photosensitive layer arranged in parallel with the light emitting layer along an in-plane direction of the substrate. The light emitting element and the sensor may include respective portions of a first common auxiliary layer. The first common auxiliary layer may be continuous under the light emitting layer and the photosensitive layer. The first common auxiliary layer may include a hole transport material. The light emitting element and the sensor may include respective portions of a second common auxiliary layer. The second common auxiliary layer may be continuous on the light emitting layer and the photosensitive layer. The second common auxiliary layer may include an electron transport material. The photosensitive layer may include a first semiconductor layer and a second semiconductor layer. The first semiconductor layer may be close to the first common auxiliary layer. The first semiconductor layer may include a p-type semiconductor configured to absorb light of a desired wavelength spectrum. The second semiconductor layer may be close to the second common auxiliary layer. The second semiconductor layer may include an n-type semiconductor having a LUMO energy level deeper than a LUMO energy level of the electron transport material. The second semiconductor layer may have an uneven surface facing the second common auxiliary layer and may have an average roughness (Rq) of greater than or equal to about 5 nm.

In some embodiments, the LUMO energy level of the n-type semiconductor may be about 0.01 eV to about 1.0 eV deeper than the LUMO energy level of the electron transport material.

In some embodiments, the LUMO energy level of the n-type semiconductor may be greater than about 2.9 eV and less than or equal to about 3.8 eV, and an energy band gap of the n-type semiconductor may be about 2.5 eV to about 4.0 eV.

In some embodiments, the LUMO energy level of the electron transport material may be about 2.9 eV to about 3.3 eV.

In some embodiments, the second common auxiliary layer may cover the uneven surface of the second semiconductor layer, and the second common auxiliary layer may include portions having different thicknesses according to surface roughness of the uneven surface of the second semiconductor layer.

In some embodiments, a maximum profile peak height (Rp) of a roughness profile of the uneven surface of the second semiconductor layer may be lower than a thickness of the second common auxiliary layer.

In some embodiments, an average roughness of the uneven surface of the second semiconductor layer may be about 0.14 to about 0.50 of the thickness of the second common auxiliary layer.

In some embodiments, an average roughness of the uneven surface of the second semiconductor layer is about 5 nm to about 20 nm.

In some embodiments, the light emitting layer may include at least one organic light emitting material, and a LUMO energy level of the organic light emitting material may be shallower than the LUMO energy level of the electron transport material.

In some embodiments, a difference among sublimation temperatures of the p-type semiconductor, the n-type semiconductor, and the organic light emitting material may be greater than or equal to about 0° C. and less than about 150° C. The sublimation temperature may be a temperature at which a weight loss of 10% relative to an initial weight occurs during thermogravimetric analysis at a pressure of about 10 Pa or less.

In some embodiments, the light emitting element and the sensor may further include a common electrode on the second common auxiliary layer, and the common electrode may be configured to apply a common voltage to the light emitting element and the sensor.

In some embodiments, the light emitting element may include a first light emitting element configured to emit light of a red wavelength spectrum, a second light emitting element configured to emit light of a green wavelength spectrum and a third light emitting element configured to emit light of a blue emission spectrum. The sensor may be between at least two selected from the first light emitting element, the second light emitting element, and the third light emitting element. The sensor may be configured to absorb light emitted from at least one of the first light emitting element, the second light emitting element, or the third light emitting element and then reflected by a recognition target, and convert the light into an electrical signal.

According to an example embodiment, a sensor may include a first electrode; a first common auxiliary layer on the first electrode, the first common auxiliary layer including a hole transport material; a first semiconductor layer on the first common auxiliary layer, the first semiconductor layer including a p-type semiconductor configured to absorb light of a desired wavelength spectrum; a second semiconductor layer on the first semiconductor layer, the second semiconductor layer including an n-type semiconductor; a second common auxiliary layer on the second semiconductor layer, the second common auxiliary layer including an electron transport material; and

a second electrode on the second common auxiliary layer. A LUMO energy level of the n-type semiconductor may be deeper than a LUMO energy level of the electron transport material. The second semiconductor layer may have an uneven surface facing the second common auxiliary layer and an average roughness (Rq) of greater than or equal to about 5 nm.

In some embodiments, the LUMO energy level of the n-type semiconductor may be greater than about 2.9 eV and less than or equal to about 3.8 eV. The LUMO energy level of the electron transport material may be about 2.9 eV to about 3.3 eV. A difference between the LUMO energy level of the n-type semiconductor and the LUMO energy level of the electron transport material may be greater than or equal to about 0.01 eV and less than about 1 eV.

In some embodiments, the n-type semiconductor may be a transparent semiconductor.

In some embodiments, an average roughness of the uneven surface of the second semiconductor layer is about 0.14 to about 0.50 of each thickness of the second common auxiliary layer and the second semiconductor layer.

In some embodiments, an average roughness of the uneven surface of the second semiconductor layer is about 5 nm to about 20 nm.

According to some example embodiments, an electronic device including the display panel or the sensor is provided.

A sensor may be capable of improving performance by being integrated with a display panel.

### BRIEF DESCRIPTION OF THE DRAWINGS

FIG. 1 is a plan view showing an example of a sensor-embedded display panel according to some example embodiments,

FIG. 2 is a cross-sectional view illustrating an example of a sensor-embedded display panel according to some example embodiments,

FIGS. 3A, 3B, and 3C are schematic views illustrating examples of a smart phone, a table device, and a computer as an electronic device according to some example embodiments, and

FIG. 4 is a schematic view illustrating an example of a configuration diagram of an electronic device according to some example embodiments.

### DETAILED DESCRIPTION

As used herein, expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, example embodiments will be described in detail so that a person skilled in the art would understand the same. However, a structure that is actually applied may be implemented in various different forms and is not limited to the embodiments described herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity of the embodiments, and the same or similar constituent elements are indicated by the same reference numeral throughout the specification.

Hereinafter, the terms “lower” and “upper” are used for better understanding and ease of description, but do not limit the location relationship.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-2 (Hitachi) or AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level. Hereinafter, a sensor-embedded display panel according to some example embodiments is described.

The sensor-embedded display panel according to some example embodiments may be capable of performing a display function and a recognition function (e.g., biometric recognition function), and may be an in-cell type display panel in which a sensor performing a recognition function (e.g., biometric recognition function) is embedded in the display panel.

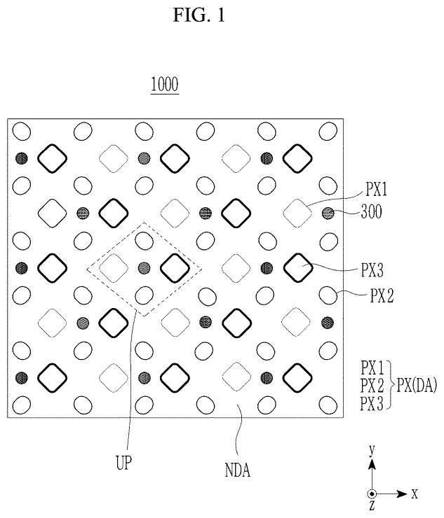

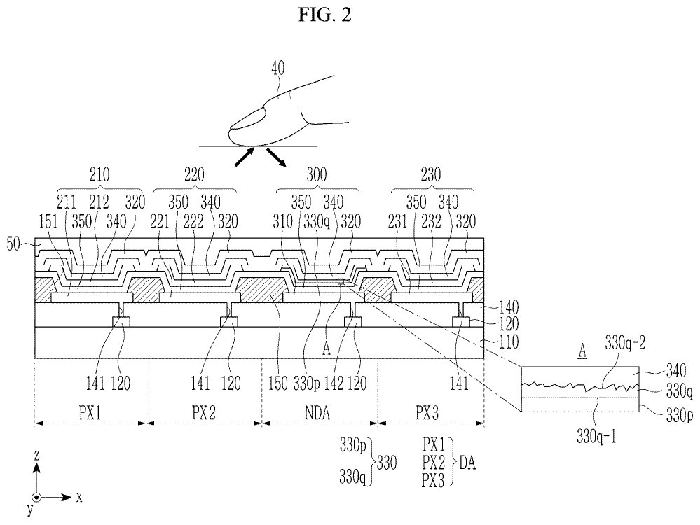

FIG. 1 is a plan view showing an example of a sensor-embedded display panel according to some example embodiments, and FIG. 2 is a cross-sectional view illustrating an example of a sensor-embedded display panel according to some example embodiments.

Referring to FIGS. 1 and 2, a sensor-embedded display panel 1000 according to some example embodiments includes a plurality of subpixels PXs displaying different colors. The plurality of subpixels PXs may be configured to display at least three primary colors, for example, a first subpixel PX1, a second subpixel PX2, and a third subpixel PX3 displaying different first color, second color, and third color selected from red, green, and blue. For example, the first color, the second color, and the third color may be red, green, and blue, respectively. The first subpixel PX1 may be a red subpixel configured to display red, the second subpixel PX2 may be a green subpixel configured to display green, and the third subpixel PX3 may be a blue subpixel configured to display blue. However, the present disclosure is not limited thereto, and an auxiliary subpixel (not shown) such as a white subpixel may be further included.

The plurality of subpixels PXs including the first subpixel PX1, the second subpixel PX2, and the third subpixel PX3 may constitute one unit pixel UP to be arranged repeatedly along the row and/or column. In FIG. 1, a structure including one first subpixel PX1, two second subpixels PX2, and one third subpixel PX3 in the unit pixel UP is illustrated, but the present disclosure is not limited thereto. At least one first subpixel PX1, at least one second subpixel PX2, or at least one third subpixel PX3 may be included in the unit pixel UP. In the drawing, as an example, an arrangement of a Pentile type is illustrated, but the present disclosure is not limited thereto. The subpixels PXs may be arranged variously. An area occupied by the plurality of subpixels PXs and displaying colors by the plurality of subpixels PXs may be a display area DA displaying an image.

Each of the first subpixel PX1, the second subpixel PX2, and the third subpixel PX3 may include a light emitting element. As an example, the first subpixel PX1 may include a first light emitting element 210 configured to emit light of a wavelength spectrum of a first color, the second subpixel PX2 may include a second light emitting element 220 configured to emit light of a wavelength spectrum of a second color, and the third subpixel PX3 may include a third light emitting element 230 configured to emit light of a wavelength spectrum of a third color. However, the present disclosure is not limited thereto, and at least one of the first subpixel PX1, the second subpixel PX2, or the third subpixel PX3 may include a light emitting element configured to emit light of a combination of a first color, a second color, and a third color, that is, light in a white wavelength spectrum, and may be configured to display a first color, a second color, or a third color through a color filter (not shown).

The sensor-embedded display panel 1000 according to some example embodiments includes a sensor 300. The sensor 300 may be disposed in a non-display area NDA. The non-display area NDA may be an area other than the display area DA, in which the first subpixel PX1, the second subpixel PX2, the third subpixel PX3, and optionally auxiliary subpixels are not disposed. The sensor 300 may be between at least two of the first subpixel PX1, the second subpixel PX2, or the third subpixel PX3, and may be in parallel with the first, second, and third light emitting elements 210, 220, and 230 in the display area DA.

The sensor 300 may be an optical type recognition sensor (e.g., a biometric sensor), and may be configured to absorb light emitted from at least one of the first, second or third light emitting elements 210, 220, and 230 in the display area DA and reflected by a recognition target 40 such as a living body, a tool, or an object, and then convert the absorbed light into an electrical signal. Herein, the living body may be a finger, a fingerprint, a palm, an iris, a face, and/or a wrist, but is not limited thereto. The sensor 300 may be, for example, a fingerprint sensor, an illumination sensor, an iris sensor, a distance sensor, a blood vessel distribution sensor, and/or a heart rate sensor, but is not limited thereto.

The sensor 300 may be in the same plane as the first, second, and third light emitting elements 210, 220, and 230 on the substrate 110, and may be embedded in the sensor-embedded display panel 1000.

Referring to FIG. 2, the sensor-embedded display panel 1000 includes a substrate 110; a thin film transistor 120 on the substrate 110; an insulation layer 140 on the thin film transistor 120; a pixel definition layer 150 on the insulation layer 140; and first, second, or third light emitting elements 210, 220, and 230 and the sensor 300 in a space defined by the pixel definition layer 150.

The substrate 110 may be a light transmitting substrate, for example, a glass substrate or a polymer substrate. The polymer substrate may include, for example, polycarbonate, polymethylmethacrylate, polyethyleneterephthalate, polyethylenenaphthalate, polyimide, polyamide, polyamideimide, polyethersulfone, polyorganosiloxane, styrene-ethylene-butylene-styrene, polyurethane, polyacrylate, polyolefin, or any combination thereof, but is not limited thereto.

A plurality of thin film transistors 120 are formed on the substrate 110. One or more thin film transistor 120 may be included in each subpixel PX, and may include, for example, at least one switching thin film transistor and/or at least one driving thin film transistor. The substrate 110 on which the thin film transistor 120 is formed may be referred to as a thin film transistor substrate (TFT substrate) or a thin film transistor backplane (TFT backplane).

The insulation layer 140 may cover the substrate 110 and the thin film transistor 120 and may be formed on the whole surface of the substrate 110. The insulation layer 140 may be a planarization layer or a passivation layer, and may include an organic insulating material, an inorganic insulating material, an organic-inorganic insulating material, or any combination thereof. The insulation layer 140 may have a plurality of contact holes 141 for connecting the first, second, and third light emitting elements 210, 220, and 230 and the thin film transistor 120 and a plurality of contact holes 142 for electrically connecting the sensor 300 and the thin film transistor 120.

The pixel definition layer 150 may also be formed on the whole surface of the substrate 110 and may be between adjacent subpixels PXs to partition each subpixel PX. The pixel definition layer 150 may have a plurality of openings 151 in each subpixel PX, and in each opening 151, any one of first, second, and third light emitting elements 210, 220, and 230 and the sensor 300 may be disposed.

The first, second and third light emitting elements 210, 220, and 230 are formed on the substrate 110 (or thin film transistor substrate), and are repeatedly arranged along the in-plane direction (e.g., xy direction) of the substrate 110. As described above, the first, second, and third light emitting elements 210, 220, and 230 may be included in the first subpixel PX1, the second subpixel PX2, and the third subpixel PX3, respectively. The first, second, and third light emitting elements 210, 220, and 230 may be electrically connected to separate thin film transistors 120 and may be driven independently.

The first, second, and third light emitting elements 210, 220, and 230 may be configured to each independently emit one light of a red wavelength spectrum, a green wavelength spectrum, a blue wavelength spectrum, and a combination thereof. For example, the first light emitting element 210 may be configured to emit light of a red wavelength spectrum, the second light emitting element 220 may be configured to emit light of a green wavelength spectrum, and the third light emitting element 230 may be configured to emit light of a blue wavelength spectrum. Herein, the red wavelength spectrum, the green wavelength spectrum, and the blue wavelength spectrum may have a maximum emission wavelength (λ_{peak,L}) in a wavelength region of greater than about 600 nm and less than about 750 nm, about 500 nm to about 600 nm, and greater than or equal to about 380 nm and less than about 500 nm, respectively.

The first, second, and third light emitting elements 210, 220, and 230 may be, for example, light emitting diodes, for example organic light emitting diodes (OLEDs) including an organic light emitting material.

The sensor 300 may be formed on the substrate 110 (or the thin film transistor substrate), and may be randomly or regularly arranged along the in-plane direction (e.g., xy direction) of the substrate 110. As described above, the sensor 300 may be in the non-display area NDA, and may be connected to a separate thin film transistor 120 to be independently driven. The sensor 300 may be configured to absorb light belonging to a wavelength spectrum of the light emitted from at least one of the first, second, or third light emitting elements 210, 220, and 230 and then convert the absorbed light into an electrical signal. For example, the sensor 300 may be configured to absorb light of a red wavelength spectrum, a green wavelength spectrum, a blue wavelength spectrum, and a combination thereof, and then convert the absorbed light into an electrical signal, and for example, light of a green wavelength spectrum may be absorbed and converted into an electrical signal. The sensor 300 may be, for example, a photoelectric conversion diode, for example an organic photoelectric conversion diode including an organic photoelectric conversion material.

Each of the first, second, and third light emitting elements 210, 220, and 230 and the sensor 300 may include a pixel electrode 211, 221, 231, and 310; a common electrode 320 facing the pixel electrodes 211, 221, 231, and 310, and to which a common voltage is applied; and light emitting layers 212, 222, and 232 or a photosensitive layer 330, a first common auxiliary layer 350, and a second common auxiliary layer 340 between the pixel electrode 211, 221, 231, and 310 and the common electrode 320.

The first, second, and third light emitting elements 210, 220, and 230 and the sensor 300 may be arranged in parallel along the in-plane direction (e.g., xy direction) of the substrate 110, and may share the common electrode 320, the first common auxiliary layer 350, and the second common auxiliary layer 340 which are formed on the whole surface of the substrate 110.

The common electrode 320 is continuously formed on the light emitting layers 212, 222, and 232 and the photosensitive layer 330, and is substantially formed on the whole surface of the substrate 110. The common electrode 320 may apply a common voltage to the first, second, and third light emitting elements 210, 220, and 230 and the sensor 300.

The common electrode 320 may be a light transmitting electrode configured to transmit light. The light transmitting electrode may be a transparent electrode or a semi-transmissive electrode. The transparent electrode may have a light transmittance of about 85% to about 100%, about 90% to about 100%, or about 95% to about 100%, and the semi-transmissive electrode may have a light transmittance of greater than or equal to about 30% and less than about 85%, about 40% to about 80%, or about 40% to about 75%. The transparent electrode and the semi-transmissive electrode may include, for example, at least one of an oxide conductor, a carbon conductor, or a metal thin film. The oxide conductors may include, for example, one or more of indium tin oxide (ITO), indium zinc oxide (IZO), zinc tin oxide (ZTO), aluminum tin oxide (ATO), and aluminum zinc oxide (AZO), the carbon conductor may include one or more selected from graphene and carbon nanostructures, and the metal thin film may be a very thin film including aluminum (Al), magnesium (Mg), silver (Ag), gold (Au), magnesium-silver (Mg—Ag), magnesium-aluminum (Mg—Al), an alloy thereof, or any combination thereof.

The first common auxiliary layer 350 may be between the light emitting layers 212, 222, and 232 and the photosensitive layer 330 and the substrate 110, and among them, between the light emitting layers 212, 222, and 232 and the photosensitive layer 330 and the pixel electrodes 211, 221, 231, and 310. The first common auxiliary layer 350 may be connected to each other and may continuously be formed under the light emitting layers 212, 222, and 232 and the photosensitive layer 330 and on the pixel electrodes 211, 221, 231, and 310.

The first common auxiliary layer 350 may be a charge auxiliary layer (e.g., hole auxiliary layer) that facilitates injection and/or transport of charge carriers (e.g., holes) from the pixel electrodes 211, 221, and 231 to the light emitting layers 212, 222, and 232. The first common auxiliary layer 350 may include a charge transport material, for example, a hole transport material. For example, the HOMO energy level of the first common auxiliary layer 350 (e.g., hole transport material) may be between the HOMO energy level of the light emitting layers 212, 222, and 232 (the HOMO energy level of the organic light emitting material of the light emitting layer) and the work functions of the pixel electrodes 211, 221, and 231 (conductor of the pixel electrode). The work functions of the pixel electrodes 211, 221, and 231, the HOMO energy levels of the first common auxiliary layer 350, and the HOMO energy levels of the light emitting layers 212, 222, and 232 may be sequentially deepened. For example, the HOMO energy level of the first common auxiliary layer 350 (e.g., hole transport material) may be about 5.3 eV to about 5.6 eV, and may be about 5.3 eV to about 5.5 eV within the above range, but is not limited thereto.

The first common auxiliary layer 350 may include an organic material, an inorganic material, an organic-inorganic material, or any combination thereof satisfying the HOMO energy level, for example a phthalocyanine compound such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris{2-naphthyl(phenyl)amino}triphenylamine), PEDOT/PSS (poly(3,4-ethylenedioxythiophene)/poly(4-styrenesulfonate)), PAN I/DBSA (polyaniline/dodecylbenzenesulfonic acid), PANI/CSA (polyaniline/Camphor sulfonic acid), PANT/PSS (polyaniline/poly(4-styrenesulfonate)), NPB (N,N′-di(naphthalene-1-yl)-N,N′-diphenylbenzidine), polyetherketone including triphenylamine (TPAPEK), 4-isopropyl-4′-methyldiphenyliodonium[tetrakis(pentafluorophenyl)borate], HAT-CN (dipyrazino[2,3-f: 2′,3′-h] quinoxaline-2,3,6,7,10,11-hexacarbonitrile), a carbazole-based derivative such as N-phenylcarbazole, polyvinylcarbazole, and the like, a fluorene-based derivative, TPD (N,N′-bis(3-methylphenyl)-N,N′-diphenyl-[1,1-biphenyl]-4,4′-diamine), a triphenylamine-based derivative such as TCTA (4,4′,4″-tris(N-carbazolyl)triphenylamine), NPB (N,N′-di(naphthalene-1-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), or any combination thereof, but is not limited thereto. The first common auxiliary layer 350 may be one layer or two or more layers.

The second common auxiliary layer 340 may be between the light emitting layers 212, 222, and 232 and the photosensitive layer 330 and the common electrode 320, and may be connected to each other to be continuously formed on the light emitting layers 212, 222, and 232 and the photosensitive layer 330 and under the common electrode 320.

The second common auxiliary layer 340 may be a charge auxiliary layer (e.g., an electron auxiliary layer) that facilitates injection and/or transport of charges (e.g., electrons) from the common electrode 320 to the light emitting layers 212, 222, and 232. The second common auxiliary layer 340 may include a charge transport material, for example, an electron transport material. For example, the LUMO energy level of the second common auxiliary layer 340 (e.g., electron transport material) may be between the LUMO energy level of the light emitting layers 212, 222, and 232 (the organic light emitting material of the light emitting layer) and the work functions of the common electrode 320 (conductor of the common electrode). The work function of the common electrode 320, the LUMO energy level of the first common auxiliary layer 340, and the LUMO energy levels of the light emitting layers 212, 222, and 232 may sequentially become shallow. For example, the LUMO energy level of the second common auxiliary layer 340 (e.g., electron transport material) may be about 2.9 eV to about 3.3 eV, and about 3.0 to about 3.2 eV within the above range, but is not limited thereto.

The second common auxiliary layer 340 may include an organic material, an inorganic material, an organic-inorganic material, or any combination thereof satisfying the LUMO energy level, for example a halogenated metal such as LiF, NaCl, CsF, RbCl, and RbI; a lanthanides metal such as Yb; a metal oxide such as Li₂O or BaO; Liq (lithium quinolate), Alq3 (tris(8-hydroxyquinolinato)aluminum), 1,3,5-tri[(3-pyridyl)-phen-3-yl]benzene, 2,4,6-tris (3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tri(1-phenyl-1H-benzo[d]imidazol-2-yl)phenyl), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq₂ (berylliumbis(benzoquinolin-10-olate), ADN (9,10-di(naphthalene-2-yl)anthracene), BmPyPhB (1,3-bis[3,5-di(pyridin-3-yl)phenyl]benzene), or any combination thereof, but is not limited thereto. The second common auxiliary layer 340 may be one layer or two or more layers.

Each of the first, second, and third light emitting elements 210, 220, and 230 and the sensor 300 includes pixel electrodes 211, 221, 231, and 310 facing the common electrode 320. One of the pixel electrodes 211, 221, 231, and 310 and the common electrode 320 is an anode, and the other is a cathode. For example, the pixel electrodes 211, 221, 231, and 310 may be an anode, and the common electrode 320 may be a cathode. The pixel electrodes 211, 221, 231, and 310 are separated for each subpixel PX, and are electrically connected to each separate thin film transistor 120 to be independently driven.

The pixel electrodes 211, 221, 231, and 310 may be a light transmitting electrode (a transparent electrode or a semi-transmissive electrode) or a reflective electrode. The light transmitting electrode is the same as described above. The reflective electrode may include a reflective layer having a light transmittance of less than or equal to about 5% and/or a reflectance of greater than or equal to about 80%, and the reflective layer may include an optically opaque material. The optically opaque material may include a metal, a metal nitride, or any combination thereof, for example silver (Ag), copper (Cu), aluminum (Al), gold (Au), titanium (Ti), chromium (Cr), nickel (Ni), an alloy thereof, a nitride thereof (e.g., TiN), or any combination thereof, but is not limited thereto. The reflective electrode may be formed of a reflective layer or may have a stacked structure of a reflective layer/transmissive layer or a transmissive layer/reflective layer/transmissive layer, and the reflective layer may be one layer or two or more layers.

For example, when the pixel electrodes 211, 221, 231, and 310 are reflective electrodes and the common electrode 320 is a light transmitting electrode, the sensor-embedded display panel 1000 may be a top emission type display panel configured to emit light toward the opposite side of the substrate 110. For example, when the pixel electrodes 211, 221, 231, and 310 and the common electrode 320 are light transmitting electrodes, respectively, the sensor-embedded display panel 1000 may be a both side emission type display panel configured to emit light toward both the substrate 110 and the opposite side of the substrate 110.

For example, the pixel electrodes 211, 221, 231, and 310 may be reflective electrodes and the common electrode 320 may be a semi-transmissive electrode. In this case, the sensor-embedded display panel 1000 may have a microcavity structure. In the microcavity structure, reflection may occur repeatedly between the reflective electrode and the semi-transmissive electrode separated by a desired and/or alternatively predetermined optical length (e.g., a distance between the semi-transmissive electrode and the reflective electrode) and light of a desired and/or alternatively predetermined wavelength spectrum may be enhanced to improve optical properties.

For example, among the light emitted from the light emitting layers 212, 222, and 232 of the first, second, and third light emitting elements 210, 220, and 230, light of a desired and/or alternatively predetermined wavelength spectrum may be repeatedly reflected between the semi-transmissive electrode and the reflective electrode and then may be modified. Among the modified light, light of a wavelength spectrum corresponding to a resonance wavelength of a microcavity may be enhanced to exhibit amplified light emission characteristics in a narrow wavelength region. Accordingly, the sensor-embedded display panel 1000 may express colors with high color purity.

For example, among the light incident on the sensor 300, light of a desired and/or alternatively predetermined wavelength spectrum may be repeatedly reflected between the semi-transmissive electrode and the reflective electrode to be modified. Among the modified light, light having a wavelength spectrum corresponding to the resonance wavelength of a microcavity may be enhanced to exhibit photoelectric conversion characteristics amplified in a narrow wavelength region. Accordingly, the sensor 300 may exhibit high photoelectric conversion characteristics in a narrow wavelength region.

Each of the first, second, and third light emitting elements 210, 220, and 230 includes light emitting layers 212, 222, and 232 between the pixel electrodes 211, 221, and 231 and the common electrode 320. Each of the light emitting layer 212 included in the first light emitting element 210, the light emitting layer 222 included in the second light emitting element 220, and the light emitting layer 232 included in the third light emitting element 230 may be configured to emit light in the same or different wavelength spectra and may be configured to emit light in, for example a red wavelength spectrum, a green wavelength spectrum, a blue wavelength spectrum, or any combination thereof.

For example, when the first light emitting element 210, the second light emitting element 220, and the third light emitting element 230 are a red light emitting elements, a green light emitting element, and a blue light emitting element, respectively, the light emitting layer 212 may be a red light emitting layer configured to emit light in a red wavelength spectrum, the light emitting layer 222 included in the second light emitting element 220 may be a green light emitting layer configured to emit light in a green wavelength spectrum, and the light emitting layer 232 included in the third light emitting element 230 may be a blue light emitting layer configured to emit light in a blue wavelength spectrum. Herein, the red wavelength spectrum, the green wavelength spectrum, and the blue wavelength spectrum may have a peak absorption wavelength of greater than about 600 nm and less than about 750 nm, about 500 nm to about 600 nm, and greater than or equal to about 380 nm and less than about 500 nm, respectively.

For example, when at least one of the first light emitting element 210, the second light emitting element 220, or the third light emitting element 230 is a white light emitting element, the light emitting layer of the white light emitting element may be configured to emit light of a full visible light wavelength spectrum, for example, light in a wavelength spectrum of greater than or equal to about 380 nm and less than about 750 nm, about 400 nm to about 700 nm, or about 420 nm to about 700 nm.

The light emitting layers 212, 222, and 232 may include at least one host material and a fluorescent or phosphorescent dopant, and at least one of the at least one host material and the fluorescent or phosphorescent dopant may be an organic light emitting material. The organic light emitting material may include, for example, a low molecular organic light emitting material, for example, a vapor depositable organic light emitting material.

The organic light emitting material included in the light emitting layers 212, 222, 232 is not particularly limited as long as it is an electroluminescent material configured to emit light of a desired and/or alternatively predetermined wavelength spectrum, and may be, for example, perylene; rubrene; 4-(dicyanomethylene)-2-methyl-6-[p-(dimethylamino)styryl]-4H-pyran; coumarin or a derivative thereof; carbazole or a derivative thereof; TPBi (2,2′,2″-(1,3,5-benzinetriyl)-tris(1-phenyl-1-H-benzimidazole); TBADN (2-t-butyl-9,10-di(naphth-2-yl)anthracene); AND (9,10-di(naphthalene-2-yl)anthracene); CBP (4,4′-bis(N-carbazolyl)-1,1′-biphenyl); TCTA (4,4′,4″-tris(carbazol-9-yl)-triphenylamine); TPBi (1,3,5-tris(N-phenylbenzimidazole-2-yl)benzene); TBADN (3-tert-butyl-9,10-di(naphth-2-yl)anthracene); DSA (distyrylarylene); CDBP (4,4′-bis(9-carbazolyl)-2,2′-dimethyl-biphenyl); MADN (2-methyl-9,10-bis(naphthalen-2-yl)anthracene); TCP (1,3,5-tris(carbazol-9-yl)benzene); Alq3 (tris(8-hydroxyquinolino)lithium); an organometallic compound including Pt, Os, Ti, Zr, Hf, Eu, Tb, Tm, Rh, Ru, Re, Be, Mg, Al, Ca, Mn, Co, Cu, Zn, Ga, Ge, Pd, Ag, and/or Au, a derivative thereof, or any combination thereof, but is not limited thereto. The organic light emitting material included in the light emitting layers 212, 222, and 232 may be a depositable organic light emitting material that may be vaporized (sublimated) at a desired and/or alternatively predetermined temperature to be deposited, and may have a desired and/or alternatively predetermined sublimation temperature (Ts). Here, the sublimation temperature may be a temperature at which a weight loss of 10% relative to the initial weight occurs during thermogravimetric analysis (TGA) at a low pressure of about 10 Pa or less, and may be a deposition temperature during the process or a set temperature of a deposition chamber used in the process.

The sublimation temperature (Ts) of the organic light emitting material included in the light emitting layer 212, 222, and 232 may be less than or equal to about 350° C., and within the above range, less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., or less than or equal to about 250° C., about 100° C. to about 350° C., about 100° C. to about 340° C., about 100° C. to about 330° C., about 100° C. to about 320° C., about 100° C. to about 310° C., about 100° C. to about 300° C., about 100° C. to about 290° C., about 100° C. to about 280° C., about 100° C. to about 270° C., about 100° C. to about 260° C., about 100° C. to about 250° C., about 150° C. to about 350° C., about 150° C. to about 340° C., about 150° C. to about 330° C., about 150° C. to about 320° C., about 150° C. to about 310° C., about 150° C. to about 300° C., about 150° C. to about 290° C., about 150° C. to about 280° C., about 150° C. to about 270° C., about 150° C. to about 260° C., or about 150° C. to about 250° C. When the organic light emitting material has a sublimation temperature within the above range, it may be effectively deposited without substantial decomposition and/or deterioration of the organic light emitting material.

The sensor 300 includes a photosensitive layer 330 between the pixel electrode 310 and the common electrode 320. The photosensitive layer 330 may be between the first common auxiliary layer 350 and the second common auxiliary layer 340. The photosensitive layer 330 may be disposed in parallel with the light emitting layers 212, 222, and 232 of the first, second, and third light emitting elements 210, 220, and 230 along the in-plane direction (e.g., xy direction) of the substrate 110. The photosensitive layer 330 and the light emitting layers 212, 222, and 232 may be disposed at the same plane.

The photosensitive layer 330 may be a photoelectric conversion layer configured to absorb light of a desired and/or alternatively predetermined wavelength spectrum and convert the absorbed light into an electrical signal, and may be configured to absorb the light emitted from at least one of the aforementioned first, second, and third light emitting elements 210, 220, and 230 and then reflected by the recognition target 40 and may be configured to convert it into an electrical signal. The photosensitive layer 330 may be configured to absorb light of, for example, a red wavelength spectrum, a green wavelength spectrum, a blue wavelength spectrum, or any combination thereof.

For example, the photosensitive layer 330 may be configured to selectively absorb light of a green wavelength spectrum having a peak absorption wavelength (λ_{peak,A}) in a wavelength region of about 500 nm to about 600 nm, and may be configured to absorb light that is emitted from the green light emitting element among the first, second, and third light emitting elements 210, 220, and 230 and then reflected by the recognition target 40. The peak absorption wavelength (λ_{peak,A}) of the photosensitive layer 330 may belong to about 510 nm to about 580 nm, about 520 nm to about 570 nm, about 520 nm to about 560 nm, or about 520 nm to about 550 nm within the above range.

The photosensitive layer 330 includes a first semiconductor layer 330p close to the first common auxiliary layer 350 and a second semiconductor layer 330q close to the second common auxiliary layer 340. The first semiconductor layer 330p and the second semiconductor layer 330q may form a pn junction, and after receiving light from the outside to generate excitons, the generated excitons are separated into holes and electrons to be transported into a pixel electrode 310 and the common electrode 320, respectively.

The first semiconductor layer 330p may include a p-type semiconductor configured to absorb light of the desired and/or alternatively predetermined wavelength spectrum. The p-type semiconductor may be configured to absorb, for example, at least a portion of the visible light wavelength spectrum, and may be configured to absorb light of, for example, a red wavelength spectrum, a green wavelength spectrum, a blue wavelength spectrum, or any combination thereof. The p-type semiconductor may be, for example, an organic light absorbing material, and may be a low molecular light absorbing material that may be vaporized (sublimed) and deposited at a desired and/or alternatively predetermined temperature while exhibiting the aforementioned photoelectric conversion characteristics.

The p-type semiconductor may have an energy level capable of forming effective electrical matching with the adjacent first common auxiliary layer 350 so that holes separated from excitons may be effectively moved and/or extracted toward the pixel electrode 310. For example, a difference between the HOMO energy level of the first common auxiliary layer 350 and the HOMO energy level of the p-type semiconductor may be less than about 1.0 eV, within the above range, less than or equal to about 0.9 eV, less than or equal to about 0.8 eV, less than or equal to about 0.7 eV, or less than or equal to about 0.5 eV, greater than or equal to about 0 eV and less than about 1.0 eV, about 0 eV to about 0.9 eV, about 0 eV to about 0.8 eV, about 0 eV to about 0.7 eV, about 0 eV to about 0.5 eV, greater than or equal to about 0.01 eV and less than about 1.0 eV, about 0.01 eV to about 0.9 eV, about 0.01 eV to about 0.8 eV, about 0.01 eV to about 0.7 eV, or about 0.01 eV to about 0.5 eV.

The sublimation temperature of the p-type semiconductor may be less than or equal to about 300° C., within the above range, less than or equal to about 290° C., less than or equal to about 280° C., less than or equal to about 270° C., less than or equal to about 260° C., or less than or equal to about 250° C., about 100° C. to about 300° C., about 100° C. to about 290° C., about 100° C. to about 280° C., about 100° C. to about 270° C., about 100° C. to about 260° C., about 100° C. to about 250° C., about 150° C. to about 300° C., about 150° C. to about 290° C., about 150° C. to about 280° C., about 150° C. to about 270° C., about 150° C. to about 260° C., about 150° C. to about 250° C., about 200° C. to about 300° C., about 200° C. to about 290° C., about 200° C. to about 280° C., about 200° C. to about 270° C., about 200° C. to about 260° C., or about 200° C. to about 250° C.

The second semiconductor layer 330q may include an n-type semiconductor. The n-type semiconductor may be, for example, a transparent semiconductor that does not substantially absorb light in the visible wavelength spectrum. The transparent semiconductor may have a wide energy bandgap so as not to substantially absorb light of a visible wavelength spectrum, for example, an energy bandgap of greater than or equal to about 2.5 eV and within the range, for example, an energy bandgap of about 2.5 eV to about 4.0 eV.

The n-type semiconductor may have an energy level capable of effectively forming a pn junction with a p-type semiconductor, and accordingly, it is effective to have a relatively deep LUMO energy level for high charge separation efficiency from excitons. For example, the LUMO energy level of the n-type semiconductor may be greater than about 2.9 eV, within the range, greater than or equal to about 3.0 eV, greater than or equal to about 3.1 eV, or greater than or equal to about 3.2 eV, and within the range, greater than about 2.9 eV and less than or equal to about 3.8 eV, about 3.0 eV to about 3.8 eV, about 3.1 eV to about 3.8 eV, or about 3.2 eV to about 3.8 eV.

The LUMO energy level of the n-type semiconductor may be deeper than that of the second common auxiliary layer 340 (e.g., electron transport material). For example, the LUMO energy level of the n-type semiconductor may be less than about 1.0 eV deeper than that of the second common auxiliary layer 340, within the range, less than or equal to about 0.9 eV, less than or equal to about 0.8 eV, less than or equal to about 0.7 eV, or less than or equal to about 0.5 eV much deeper, and greater than or equal to about 0.01 eV and less than about 1.0 eV, about 0.01 eV to about 0.9 eV, about 0.01 eV to about 0.8 eV, about 0.01 eV to about 0.7 eV, or about 0.01 eV to about 0.5 eV much deeper.

On the other hand, as mentioned above, when the n-type semiconductor has relatively deeper LUMO energy for the high charge separation efficiency from excitons in the photosensitive layer 330, the LUMO energy level of the n-type semiconductor may be mismatched with that of the second common auxiliary layer 340, deteriorating transport and/or extraction efficiency of electrons. In other words, in order to effectively transport and/or extract the electrons toward the common electrode 320, the LUMO energy level of the second semiconductor layer 330q (n-type semiconductor) should be more shallow than that of the second common auxiliary layer 340 (electron transport material), and the LUMO energy level of the second common auxiliary layer 340 (electron transport material should be more shallow than that of the common electrode 320 (conductor), so that the electrons may be transported through the stair-type LUMO energy levels, but as described above, when the n-type semiconductor having relatively deep LUMO energy is adopted for the high charge separation efficiency in the photosensitive layer 330, the LUMO energy level of the second common auxiliary layer 340 becomes more shallow than that of the second semiconductor layer 330q (n-type semiconductor), deteriorating transport and/or extraction efficiency of the electrons. In other words, depending on a LUMO level of the n-type semiconductor, the charge separation efficiency may have trade-off relationship with the electron transport and/or extraction efficiency.

The present inventors have confirmed that the electron transport and/or extraction efficiency may also be improved by applying desired and/or alternatively predetermined roughness onto the surface of the second semiconductor layer 330q facing the second common auxiliary layer 340. In other words, the second semiconductor layer 330q may have a lower surface 330q-1 facing the first semiconductor layer 330p and an upper surface 330q-2 facing the second common auxiliary layer 340, wherein the upper surface 330q-2 of the second semiconductor layer 330q facing the second common auxiliary layer 340 may be an uneven surface having relatively high surface roughness. This uneven surface of the second semiconductor layer 330q may be, formed, for example by controlling crystal sizes of the n-type semiconductor, and for example by widening a distribution of the crystal sizes of the n-type semiconductor. The crystal sizes of the n-type semiconductor may be controlled, for example by a deposition speed or a temperature and/or time of a heat treatment after the deposition, but inventive concepts are not limited thereto.

The surface roughness may be an example of surface flatness, wherein the lower the surface roughness, the higher the surface flatness, and the higher the surface roughness, the lower the surface flatness due to the more irregular concavo-convex. For example, the surface roughness may be evaluated by average roughness (Rq), wherein the average roughness (Rq) may be a root-mean-square (Rq), which is a square root of square values of each height and depth from a mean line of the uneven surface. The average roughness (Rq) may be obtained by using for example, an atomic force microscope (AFM) to obtain a surface morphology image of a desired and/or alternatively predetermined area (e.g., about 5 μm×about 5 μm) and calculating average roughness of the image. The atomic force microscope may be for example, a Dimension Icon model (Bruker Corporation).

For example, the upper surface 330q-2 of the second semiconductor layer 330q facing the second common auxiliary layer 340 may have average roughness (Rq) of greater than or equal to about 5 nm and within the range, about 5 nm to about 20 nm, about 5 nm to about 18 nm, about 5 nm to about 15 nm, or about 5 nm to about 12 nm. When the upper surface 330q-2 of the second semiconductor layer 330q has average roughness (Rq) within the range, even though the second semiconductor layer 330q includes an n-type semiconductor having relatively deep LUMO energy, the deterioration of the electron transport and/or extraction efficiency may be prevented.

For example, the average roughness (Rq) of the upper surface 330q-2 of the second semiconductor layer 330q may be greater than or equal to about 0.14, and within the above range, about 0.14 to about 0.50, about 0.14 to about 0.40, about 0.14 to about 0.35 or about 0.14 to about 0.30 of the thickness of the second semiconductor layer 330q.

For example, the average roughness (Rq) of the upper surface 330q-2 of the second semiconductor layer 330q may be greater than or equal to about 0.14, and within the above range, about 0.14 to about 0.50, about 0.14 to about 0.40, about 0.14 to about 0.35, or about 0.14 to about 0.30 of the thickness of the second common auxiliary layer 340.

For example, the surface roughness may be evaluated by a maximum profile peak height (Rp) of a roughness profile. The maximum profile peak height (Rp) of the roughness profile is a vertical distance from the highest height to the deepest depth. The maximum profile peak height (Rp) of the roughness profile may be obtained by using, for example an atomic microscope (AFM) to obtain a surface morphology image of a desired and/or alternatively predetermined area (e.g., about 5 μm×about 5 μm) and measuring the vertical distance from the highest height to the deepest depth of a line profile of the image, wherein the atomic microscope is, for example, a Dimension Icon model manufactured by Bruker Corporation. Alternatively, the maximum profile peak height (Rp) of the roughness profile may be obtained by using, for example, a focused ion beam scanning electron microscope (FIB SEM) to obtain an image of a cross-section profile and measuring the vertical distance from the highest height to the deepest depth of the profile of the image, wherein the focused ion beam scanning electron microscope is Helios NanoLab 450 (Nanolab Technologies Inc.).

For example, the maximum profile peak height (Rp) of the roughness profile of the upper surface 330q-2 of the second semiconductor layer 330q facing the second common auxiliary layer 340 may be greater than or equal to about 7 nm and may be lower than a thickness of the second common auxiliary layer 340. For example, the maximum profile peak height (Rp) of the roughness profile of the upper surface 330q-2 of the second semiconductor layer 330q facing the second common auxiliary layer 340 may be about 7 nm to about 30 nm and within the range, about 10 nm to about 30 nm, about 12 nm to about 30 nm, or about 15 nm to about 30 nm. When the maximum profile peak height (Rp) of the roughness profile of the upper surface 330q-2 of the second semiconductor layer 330q is within the ranges, even though the n-type semiconductor having relatively deep LUMO energy is included in the second semiconductor layer 330q, the deterioration of the electron transport and/or extraction efficiency may be prevented.

The second common auxiliary layer 340 may cover the uneven surface of the second semiconductor layer 330q and thus have an uneven thickness depending on a surface roughness of the second semiconductor layer 330q. For example, the second common auxiliary layer 340 covering a portion having high surface roughness of the uneven surface of the second semiconductor layer 330q may be relatively thin, while the second common auxiliary layer 340 covering a portion having low surface roughness of the uneven surface of the second semiconductor layer 330q may be relatively thick. For example, the second common auxiliary layer 340 covering a portion having the maximum profile peak height (Rp) of the roughness profile of the uneven surface 330q-2 of the second semiconductor layer 330q may be the thinnest.

As described above, the second semiconductor layer 330q of the sensor 300 includes an n-type semiconductor having a relatively deep LUMO energy level and thus may increase charge separation efficiency from excitons and simultaneously, has an uneven surface having relatively high surface roughness of greater than or equal to about 5 nm and thus may prevent the deterioration of the electron transport and/or extraction efficiency toward the second common auxiliary layer 340. Accordingly, the sensor 300 may simultaneously satisfy the charge separation efficiency and the electron transport and/or extraction efficiency, which are in a trade-off relationship.

Meanwhile, the p-type semiconductor of the first semiconductor layer 330p and the n-type semiconductor of the second semiconductor layer 330q may have a relatively small difference in sublimation temperature so that they may be successively deposited in the same chamber. For example, a difference between the sublimation temperatures of the p-type semiconductor and n-type semiconductor may be less than about 150° C., within the above range, for example less than or equal to about 140° C., less than or equal to about 130° C., less than or equal to about 120° C., less than or equal to about 110° C., less than or equal to about 100° C., less than or equal to about 90° C., less than or equal to about 80° C., less than or equal to about 70° C., less than or equal to about 60° C., less than or equal to about 50° C., less than or equal to about 40° C., less than or equal to about 30° C., less than or equal to about 20° C., less than or equal to about 15° C., or less than or equal to about 10° C., within the above range, greater than or equal to about 0° C. and less than about 150° C., about 0° C. to about 140° C., about 0° C. to about 130° C., about 0° C. to about 120° C., about 0° C. to about 110° C., about 0° C. to about 100° C., about 0° C. to about 90° C., about 0° C. to about 80° C., about 0° C. to about 70° C., about 0° C. to about 60° C., about 0° C. to about 50° C., about 0° C. to about 40° C., about 0° C. to about 30° C., about 0° C. to about 20° C., about 0° C. to about 15° C., about 0° C. to about 10° C., greater than or equal to about 2° C. and less than about 150° C., about 2° C. to about 140° C., about 2° C. to about 130° C., about 2° C. to about 120° C., about 2° C. to about 110° C., about 2° C. to about 100° C., about 2° C. to about 90° C., about 2° C. to about 80° C., 2° C. to about 70° C., about 2° C. to about 60° C., about 2° C. to about 50° C., about 2° C. to about 40° C., about 2° C. to about 30° C., about 2° C. to about 20° C., about 2° C. to about 15° C., or about 2° C. to about 10° C.

For example, the sublimation temperature of the n-type semiconductor may be less than or equal to about 380° C., within the above range, less than or equal to about 360° C., less than or equal to about 350° C., less than or equal to about 330° C., less than or equal to about 320° C., less than or equal to about 300° C., less than or equal to about 280° C., less than or equal to about 270° C., less than or equal to about 260° C., or less than or equal to about 250° C., about 100° C. to about 380° C., about 100° C. to about 360° C., about 100° C. to about 350° C., about 100° C. to about 330° C., about 100° C. to about 320° C., about 100° C. to about 300° C., about 100° C. to about 280° C., about 100° C. to about 270° C., about 100° C. to about 260° C., about 100° C. to about 250° C., about 150° C. to about 380° C., about 150° C. to about 360° C., about 150° C. to about 350° C., about 150° C. to about 330° C., about 150° C. to about 320° C., about 150° C. to about 300° C., about 150° C. to about 290° C., about 150° C. to about 280° C., about 150° C. to about 270° C., about 150° C. to about 260° C., about 150° C. to about 250° C., about 200° C. to about 380° C., about 200° C. to about 360° C., about 200° C. to about 350° C., about 200° C. to about 330° C., about 200° C. to about 320° C., about 200° C. to about 300° C., about 200° C. to about 290° C., about 200° C. to about 280° C., about 200° C. to about 270° C., about 200° C. to about 260° C., or about 200° C. to about 250° C.

For example, the sublimation temperatures of the p-type semiconductor and n-type semiconductor may be less than or equal to about 300° C., respectively, and may be about 100° C. to about 300° C. within the above range.

For example, as described above, the light emitting layers 212, 222, and 232 of the light emitting elements 210, 220, and 230 may include organic light emitting materials, and the organic light emitting materials of the light emitting layers 212, 222, and 232 and the p-type and n-type semiconductors of the photosensitive layer 330 may be vacuum-deposited in the same chamber. Accordingly, differences between the sublimation temperatures of the organic light emitting materials of the light emitting layers 212, 222, and 232 and the p-type and n-type semiconductors of the photosensitive layer 330 may be relatively small, and for example, the differences in the sublimation temperatures of the organic light emitting materials and the p-type and n-type semiconductors may be less than about 150° C., within the above range, for example less than or equal to about 140° C., less than or equal to about 130° C., less than or equal to about 120° C., less than or equal to about 110° C., less than or equal to about 100° C., less than or equal to about 90° C., less than or equal to about 80° C., less than or equal to about 70° C., less than or equal to about 60° C., less than or equal to about 50° C., less than or equal to about 40° C., less than or equal to about 30° C., less than or equal to about 20° C., less than or equal to about 15° C., or less than or equal to about 10° C., within the above range, greater than or equal to about 0° C. and less than about 150° C., about 0° C. to about 140° C., about 0° C. to about 130° C., about 0° C. to about 120° C., about 0° C. to about 110° C., about 0° C. to about 100° C., about 0° C. to about 90° C., about 0° C. to about 80° C., about 0° C. to about 70° C., about 0° C. to about 60° C., about 0° C. to about 50° C., about 0° C. to about 40° C., about 0° C. to about 30° C., about 0° C. to about 20° C., about 0° C. to about 15° C., about 0° C. to about 10° C., greater than or equal to about 2° C. and less than about 150° C., about 2° C. to about 140° C., about 2° C. to about 130° C., about 2° C. to about 120° C., about 2° C. to about 110° C., about 2° C. to about 100° C., about 2° C. to about 90° C., about 2° C. to about 80° C., about 2° C. to about 70° C., about 2° C. to about 60° C., about 2° C. to about 50° C., about 2° C. to about 40° C., about 2° C. to about 30° C., about 2° C. to about 20° C., about 2° C. to about 15° C., or about 2° C. to about 10° C.

For example, the sublimation temperatures of the organic light emitting materials of the light emitting layer 212, 222, and 232 may be less than or equal to about 350° C., within the above range, less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., or less than or equal to about 250° C., about 100° C. to about 350° C., about 100° C. to about 340° C., about 100° C. to about 330° C., about 100° C. to about 320° C., about 100° C. to about 310° C., about 100° C. to about 300° C., about 100° C. to about 290° C., about 100° C. to about 280° C., about 100° C. to about 270° C., about 100° C. to about 250° C., about 150° C. to about 350° C., about 150° C. to about 340° C., about 150° C. to about 330° C., about 150° C. to about 320° C., about 150° C. to about 310° C., about 150° C. to about 300° C., about 150° C. to about 290° C., about 150° C. to about 280° C., about 150° C. to about 270° C., or about 150° C. to about 250° C.

For example, the sublimation temperatures of the organic light emitting materials of the light emitting layers 212, 222, and 232, the p-type and n-type semiconductors of the photosensitive layer 330 may be less than or equal to about 300° C., respectively, and within the above range, about 100° C. to about 300° C.

As described above, the p-type and the n-type semiconductors of the photosensitive layer 330 have high charge separation efficiency and may form effective electrical matching with the first and second common auxiliary layers 350 and 340, respectively. Since the organic light emitting materials of the light emitting layers 212, 222, and 232 and the p-type and n-type semiconductors of the photosensitive layer 330 have thermal characteristics in a similar range, the sensor may be effectively provided in the display panel without degradation of electrical characteristics and complexity of the process.

Each thickness of the light emitting layers 212, 222, and 232 and the photosensitive layer 330 may each independently be about 5 nm to about 300 nm, about 10 nm to about 250 nm, about 20 nm to about 200 nm, or about 30 nm to about 180 nm within the above range. Differences between the thicknesses of the light emitting layers 212, 222, and 232 and the photosensitive layer 330 may be less than or equal to about 20 nm, less than or equal to about 15 nm, less than or equal to about 10 nm, or less than or equal to about 5 nm within the above range, and the thicknesses of the light emitting layers 212, 222, and 232 and the photosensitive layer 330 may be substantially the same.

On the first, second and third light emitting elements 210, 220, and 230 and the sensor 300, the encapsulation layer 50 is formed. The encapsulation layer 50 may include, for example, a glass plate, a metal thin film, an organic layer, an inorganic layer, an organic/inorganic layer, or any combination thereof. The organic layer may include, for example, an acrylic resin, a (meth)acrylic resin, polyisoprene, a vinyl resin, an epoxy resin, a urethane resin, a cellulose resin, a perylene resin, or any combination thereof, but is not limited thereto. The inorganic layer may include, for example, oxide, nitride, and/or oxynitride, for example, silicon oxide, silicon nitride, silicon oxynitride, aluminum oxide, aluminum nitride, aluminum oxynitride, zirconium oxide, zirconium nitride, zirconium oxynitride, titanium oxide, titanium nitride, titanium oxynitride, hafnium oxide, hafnium nitride, hafnium oxynitride, tantalum oxide, tantalum nitride, tantalum oxynitride, lithium fluoride, or any combination thereof, but is not limited thereto. The organic/inorganic layer may include, for example, polyorganosiloxane but is not limited thereto. The encapsulation layer 50 may have one layer or two or more layers.

As described above, the sensor-embedded display panel 1000 according to the present embodiment includes the first, second, and third light emitting elements 210, 220, and 230 configured to emit light in a desired and/or alternatively predetermined wavelength spectrum to display colors, and the sensor 300 configured to absorb light reflected by the recognition target 40 and convert it into an electrical signal, in the same plane on the substrate 110, thereby performing a display function and a recognition function (e.g., biometric recognition function). Accordingly, unlike conventional display panels formed outside the display panel or formed under the display panel by manufacturing the sensor as a separate module, it may improve performance without increasing the thickness, implementing a slim-type high performance sensor-embedded display panel 1000.

In addition, since the sensor 300 uses light emitted from the first, second, and third light emitting elements 210, 220, and 230, a recognition function (e.g., biometric recognition function) may be performed without a separate light source. Therefore, it is not necessary to provide a separate light source outside the display panel, thereby preventing a decrease in the aperture ratio of the display panel due to the area occupied by the light source, and at the same time saving power consumed by the separate light source to improve power consumption.

In addition, since the sensor 300 may be disposed anywhere in the non-display area NDA, they may be disposed at a desired location of the sensor-embedded display panel 1000 as many as desired. Therefore, for example, by randomly or regularly arranging the sensor 300 over the entire sensor-embedded display panel 1000, the biometric recognition function may be performed on any portion of the screen of an electronic device such as a mobile device and the biometric recognition function may be selectively performed only in a specific location where the biometric recognition function is required.

In addition, as described above, the first, second, and third light emitting elements 210, 220, and 230 and the sensor 300 share the common electrode 320, the first common auxiliary layer 350, and the second common auxiliary layer 340 and thus the structure and process may be simplified compared with the case where the first, second, and third light emitting elements 210, 220, and 230 and the sensor 300 are formed in separate processes.

In addition, as described above, the second semiconductor layer 330q of the sensor 300 includes an n-type semiconductor having a relatively deep LUMO energy level and thus may increase the charge separation efficiency from excitons and simultaneously, has an uneven surface having a relatively high surface roughness of greater than or equal to about 5 nm and thus may prevent the deterioration of the electron transport and/or extraction efficiency toward the second common auxiliary layer 340. Accordingly, even in the structure that the first, second, and third light emitting elements 210, 220, and 230 with the sensor 300 share the second common auxiliary layer 340, the charge separation efficiency and the electron transport and/or extraction efficiency may be simultaneously satisfied without deteriorating the electron transport and/or extraction efficiency of the sensor 300.

In addition, as described above, the organic light emitting material included in the light emitting layers 212, 222, and 232 of the first, second, and third light emitting elements 210, 220, and 230 and the p-type and n-type semiconductors included in the photosensitive layer 330 of the sensor 300 have a sublimation temperature within the desired and/or alternatively predetermined ranges and may be deposited in a continuous process in the same chamber. Accordingly, the first, second, and third light emitting elements 210, 220, and 230 and the sensor 300 may be manufactured in one process and thus realize a display panel conducting both a display function and a recognition function (e.g., a biometric recognition function) without a substantial additional process.

In addition, the sensor 300 may be an organic sensor including an organic photosensitive layer and have more than twice light absorption, compared with an inorganic diode such as a silicon photodiode, and thus a higher sensing function with a thinner thickness.

The aforementioned sensor-embedded display panel 1000 may be applied to electronic devices such as various display devices. Electronic devices such as display devices may be applied to, for example, mobile phones, video phones, smart phones, mobile phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

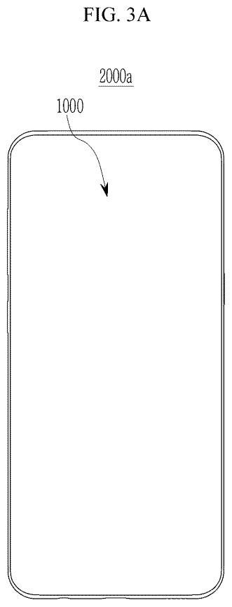

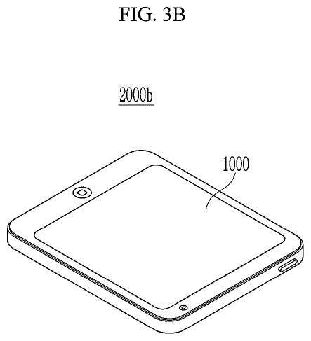

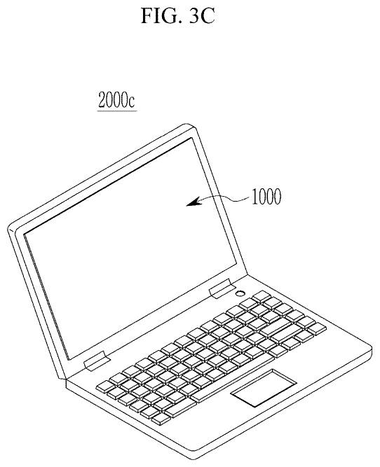

FIG. 3A is a schematic view illustrating an example of a smart phone as an electronic device according to an example.

Referring to FIG. 3A, the electronic device 2000a according to some example embodiments may include the aforementioned sensor-embedded display panel 1000, and the sensor 300 on the whole or a portion of the sensor-embedded display panel 1000, and thus a biometric recognition function may be performed on any portion of the screen, and according to the user's selection, the biometric recognition function may be selectively performed only at a specific location where the biometric recognition function is required.

An example of a method of recognizing the recognition target 40 in an electronic device 2000a such as a display device may include, for example, driving the first, second, and third light emitting elements 210, 220, and 230 of the sensor-embedded display panel 1000 and the sensor 300 to detect the light reflected from the recognition target 40 among the light emitted from the first, second, and third light emitting elements 210, 220, and 230, in the sensor 300; comparing the image of the recognition target 40 stored in advance with the image of the recognition target 40 detected by the sensor 300; and judging the consistency of the compared images and if they match according to the determination that recognition of the recognition target 40 is complete, turning off the sensor 300, permitting user's access to the display device, and driving the sensor-embedded display panel 1000 to display an image.

While FIG. 3A illustrates an example of a smart phone as an electronic device according to some example embodiments, example embodiments are not limited thereto and inventive concepts may be embodied in other types of electronic devices. For example, as depicted in FIGS. 3B and 3C, according to some example embodiments, an electronic device 2000b in the form of a tablet device and an electronic device 2000c in the form of a computer may include the aforementioned sensor-embedded display panel 1000, and the photosensor 300 in the whole or a portion of the sensor-embedded display panel 1000, and thus a biometric recognition function may be performed on any portion of the screen, and according to the user's selection, the biometric recognition function may be selectively performed only at a specific location where the biometric recognition function is required.

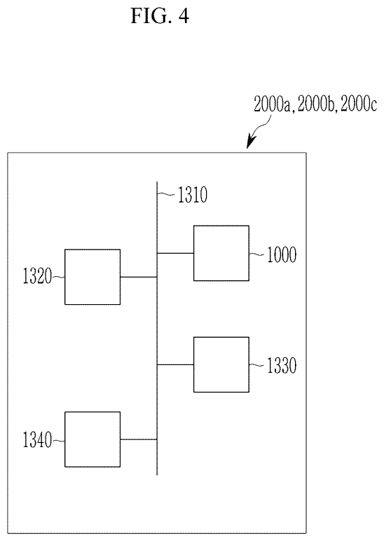

FIG. 4 is a schematic view illustrating an example of a configuration view of an electronic device according to some example embodiments.

Referring to FIG. 4, in addition to the aforementioned constituent elements (e.g., the sensor-embedded display panel 1000), the electronic device 2000a, 2000b, or 2000c may further include a bus 1310, a processor 1320, a memory 1330, and at least one additional device 1340. Information of the aforementioned sensor-embedded display panel 1000, processor 1320, memory 1330, and at least one additional device 1340 may be transmitted to each other through the bus 1310.

The processor 1320 may include one or more articles (e.g., units, instances, etc.) of processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 1320 may, for example, control a display operation of the sensor-embedded display panel 1000 or control a sensor operation of the sensor 300.

The memory 1330 may be a non-transitory computer readable storage medium, such as, for example, as a solid state drive (SSD) and may store an instruction program (e.g., program of instructions), and the processor 1320 may perform a function related to the sensor-embedded display panel 1000 by executing the stored instruction program.

The one or more additional devices 1340 may be one or more communication interfaces (e.g., wireless communication interfaces, wired interfaces), user interfaces (e.g., keyboard, mouse, buttons, etc.), power supply and/or power supply interfaces, or any combination thereof.

One or more of units, elements, and/or modules described herein may be implemented using hardware constituent elements and software constituent elements. The units and/or modules described herein may include, may be included in, and/or may be implemented by one or more articles of processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

The method according to any of the example embodiments may be recorded in a non-transitory computer readable storage device including program instructions for implementing various operations of any of the example embodiments. The storage device may also include program instructions, data files, data structures, and the like alone or in combination. The program instructions recorded in the storage device may be specially designed for the present embodiment or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of any of the example embodiments.

Hereinafter, some example embodiments are illustrated in more detail with reference to examples. However, the scope of inventive concepts is not limited to the examples.

### Example: Manufacture of Sensors

### Example 1-1

Al (10 nm), ITO (100 nm), and Al (8 nm) are sequentially deposited on the glass substrate to form a lower electrode (work function: 4.9 eV) having an Al/ITO/Al structure. Subsequently, N,N′-bis(3-methylphenyl)-N,N′-diphenyl-[1,1-biphenyl]-4,4′-diamine is deposited on the lower electrode to form a hole auxiliary layer (HOMO: 5.3 eV to 5.6 eV, LUMO: 2.0 eV to 2.3 eV). On the hole auxiliary layer, Compound A having properties shown in Table 1 (p-type semiconductor) is deposited to form a 10 nm-thick p-type semiconductor layer. On the p-type semiconductor layer, Compound B having properties shown in Table 1 (n-type semiconductor) is deposited at 0.35 Å/s to form a 40 nm-thick n-type semiconductor layer, resultantly forming a bi-layered photosensitive layer. On the bi-layered photosensitive layer, 4,7-diphenyl-1,10-phenanthroline is deposited to form a 36 nm-thick electron auxiliary layer (HOMO: 6.1 eV to 6.4 eV, LUMO: 2.9 eV to 3.1 eV). Subsequently, on the electron auxiliary layer, magnesium and silver are deposited to form an Mg:Ag upper electrode, and thus manufacturing a sensor.

### Example 1-2

A sensor is manufactured in the same manner as in Example 1-1 except that Compound B is deposited at 1.0 Å/s instead of 0.35 Å/s to form a 40 nm-thick n-type semiconductor layer.

### Example 1-3

A sensor is manufactured in the same manner as in Example 1-1 except that Compound B is deposited at 3.0 Å/s instead of 0.35 Å/s to form a 40 nm-thick n-type semiconductor layer.

### Comparative Example 1-1

A sensor is manufactured in the same manner as in Example 1-1 except that Compound B is deposited at 10.0 Å/s instead of 0.35 Å/s to form a 40 nm-thick n-type semiconductor layer.

### Example 2-1

A sensor is manufactured in the same manner as in Example 1-1 except that Compound C having properties shown in Table 1 instead of Compound B is deposited at 0.35 Å/s.

### Comparative Example 2-1

A sensor is manufactured in the same manner as in Example 2-1 except that Compound C is deposited at 3.0 Å/s instead of 0.35 Å/s.

### Comparative Example 2-2

A sensor is manufactured in the same manner as in Example 2-1 except that Compound C is deposited at 10.0 Å/s instead of 0.35 Å/s to form a 40 nm-thick n-type semiconductor layer.

TABLE 1

| | p-type | | |
|---|---|---|---|
| | semiconductor | n-type semiconductor | |
| | Compound A | Compound B | Compound C |
| Molecular weight | 488.41 | 268.18 | 486.02 |
| HOMO (eV) | 5.61 | 6.31 | 6.19 |
| LUMO (eV) | 3.52 | 3.27 | 3.23 |
| Eg (eV) | 2.09 | 3.04 | 2.96 |
| λₘₐₓ (nm) | 541 | — | — |
| Tₛ (₁₀, ° C.) | 253 | 204 | 270 |
| Refractive Index, n | 2.29 | 1.66 | 1.65 |
| Extinction Coefficient, k | 0.94 | 0.01 | 0.00 |

* Eg: energy bandgap
* Tₛ₍₁₀₎: a temperature at which the weight of the sample decreases by 10% relative to the initial weight
* λₘₐₓ: maximum absorption wavelength

### Evaluation

The surface roughness of the upper surface of each n-type semiconductor layer of the sensors according to Examples and Comparative Examples are measured, and the electrical characteristics of the sensors according to Examples are measured.

The surface roughness is evaluated by obtaining average roughness (Rq) by examining an image of an area of 5 μm×5 μm of the upper surface of the n-type semiconductor layer with an atomic microscope (AFM) (Dimension Icon model, Bruker Corporation).

The electrical characteristics are evaluated from external quantum efficiency (EQE). The external quantum efficiency (EQE) may be evaluated from external quantum efficiency (EQE) at the peak absorption wavelength (λₚₑₐₖ) after allowed to stand at 85° C. for 1 hour, which may be Incident Photon to Current Efficiency (IPCE) at blue (450 nm, B), green (λₚₑₐₖ, G), and 630 nm (red, R) wavelengths at 3 V.

The results are shown in Table 2.

TABLE 2

| | Rq (nm) | EQEₘₐₓ (%, @3 V) |
|---|---|---|
| Example 1-1 | 10.6 | 25.5 |
| Example 1-2 | 8.4 | 33.1 |
| Example 1-3 | 6.55 | 38.9 |
| Comparative Example 1-1 | 3.45 | 4.0 |
| Example 2-1 | 8.47 | 57.7 |
| Comparative Example 2-1 | 4.66 | 2.8 |
| Comparative Example 2-2 | 4.32 | 2.9 |

* Rq: average roughness

Referring to Table 2, the sensors according to Examples including an n-type semiconductor layer with relatively high surface roughness of greater than or equal to 5.0 nm exhibit improved photoelectric conversion efficiency, compared with the sensors according to Comparative Examples including an n-type semiconductor layer with relatively low surface roughness of less than 5.0 nm.

While this disclosure has been described in connection with what is presently considered to be practical example embodiments, it is to be understood that t inventive concepts are not limited to the disclosed embodiments. On the contrary, inventive concepts are intended to cover various modifications and equivalent arrangements included within the spirit and scope of the appended claims.

What is claimed is:

1. A sensor-embedded display panel, comprising
a substrate;
a light emitting element on the substrate, the light emitting element including a light emitting layer; and
a sensor on a substrate, the sensor including a photosensitive layer arranged in parallel with the light emitting layer along an in-plane direction of the substrate, wherein
the light emitting element and the sensor include respective portions of a first common auxiliary layer,
the first common auxiliary layer is continuous under the light emitting layer and the photosensitive layer,
the first common auxiliary layer includes a hole transport material, and
the light emitting element and the sensor include respective portions of a second common auxiliary layer,
the second common auxiliary layer is continuous on the light emitting layer and the photosensitive layer,
the second common auxiliary layer includes an electron transport material,
the photosensitive layer includes a first semiconductor layer and a second semiconductor layer,
the first semiconductor layer is close to the first common auxiliary layer,
the first semiconductor layer includes a p-type semiconductor configured to absorb light of a desired wavelength spectrum, and
the second semiconductor layer is close to the second common auxiliary layer, and
the second semiconductor layer includes an n-type semiconductor having a LUMO energy level deeper than a LUMO energy level of the electron transport material, and
the second semiconductor layer has an uneven surface facing the second common auxiliary layer and having an average roughness (Rq) of greater than or equal to about 5 nm.

2. The sensor-embedded display panel of claim 1, wherein the LUMO energy level of the n-type semiconductor is about 0.01 eV to about 1.0 eV deeper than the LUMO energy level of the electron transport material.

3. The sensor-embedded display panel of claim 1, wherein
the LUMO energy level of the n-type semiconductor is greater than about 2.9 eV and less than or equal to about 3.8 eV, and
an energy band gap of the n-type semiconductor is about 2.5 eV to about 4.0 eV.

4. The sensor-embedded display panel of claim 1, wherein the LUMO energy level of the electron transport material is about 2.9 eV to about 3.3 eV.

5. The sensor-embedded display panel of claim 1, wherein
the second common auxiliary layer covers the uneven surface of the second semiconductor layer, and
the second common auxiliary layer includes portions having different thicknesses according to surface roughness of the uneven surface of the second semiconductor layer.

6. The sensor-embedded display panel of claim 1, wherein a maximum profile peak height (Rp) of a roughness profile of the uneven surface of the second semiconductor layer is lower than a thickness of the second common auxiliary layer.

7. The sensor-embedded display panel of claim 1, wherein an average roughness of the uneven surface of the second semiconductor layer is about 0.14 to about 0.50 of the thickness of the second common auxiliary layer.

8. The sensor-embedded display panel of claim 1, wherein an average roughness of the uneven surface of the second semiconductor layer is about 0.14 to about 0.50 of a thickness of the second semiconductor layer.

9. The sensor-embedded display panel of claim 1, wherein an average roughness of the uneven surface of the second semiconductor layer is about 5 nm to about 20 nm.

10. The sensor-embedded display panel of claim 1, wherein
the light emitting layer includes at least one organic light emitting material, and
a LUMO energy level of the organic light emitting material is shallower than the LUMO energy level of the electron transport material.

11. The sensor-embedded display panel of claim 10, wherein
a difference among sublimation temperatures of the p-type semiconductor, the n-type semiconductor, and the organic light emitting material is greater than or equal to about 0° C. and less than about 150° C., and
the sublimation temperature is a temperature at which a weight loss of 10% relative to an initial weight occurs during thermogravimetric analysis at a pressure of about 10 Pa or less.

12. The sensor-embedded display panel of claim 1, wherein
the light emitting element and the sensor further comprise a common electrode on the second common auxiliary layer, and
the common electrode is configured to apply a common voltage to the light emitting element and the sensor.

13. The sensor-embedded display panel of claim 1, wherein
the light emitting element comprises a first light emitting element configured to emit light of a red wavelength spectrum, a second light emitting element configured to emit light of a green wavelength spectrum and a third light emitting element configured to emit light of a blue emission spectrum,
the sensor is between at least two selected from the first light emitting element, the second light emitting element, and the third light emitting element, and
the sensor is configured to absorb light emitted from at least one of the first light emitting element, the second light emitting element, or the third light emitting element and then reflected by a recognition target, and convert the light into an electrical signal.

14. An electronic device comprising the sensor-embedded display panel of claim 1.

15. A sensor, comprising
a first electrode;
a first common auxiliary layer on the first electrode, the first common auxiliary layer including a hole transport material;
a first semiconductor layer on the first common auxiliary layer, the first semiconductor layer including a p-type semiconductor configured to absorb light of a desired wavelength spectrum;
a second semiconductor layer on the first semiconductor layer, the second semiconductor layer including an n-type semiconductor;
a second common auxiliary layer on the second semiconductor layer, the second common auxiliary layer including an electron transport material; and
a second electrode on the second common auxiliary layer, wherein
a LUMO energy level of the n-type semiconductor is deeper than a LUMO energy level of the electron transport material, and
the second semiconductor layer has an uneven surface facing the second common auxiliary layer and having an average roughness (Rq) of greater than or equal to about 5 nm.

16. The sensor of claim 15, wherein
the LUMO energy level of the n-type semiconductor is greater than about 2.9 eV and less than or equal to about 3.8 eV,
the LUMO energy level of the electron transport material is about 2.9 eV to about 3.3 eV, and
a difference between the LUMO energy level of the n-type semiconductor and the LUMO energy level of the electron transport material is greater than or equal to about 0.01 eV and less than about 1 eV.

17. The sensor of claim 15, wherein the n-type semiconductor is a transparent semiconductor.

18. The sensor of claim 15, wherein
an average roughness of the uneven surface of the second semiconductor layer is about 0.14 to about 0.50 of each thickness of the second common auxiliary layer and the second semiconductor layer.

19. The sensor of claim 15, wherein an average roughness of the uneven surface of the second semiconductor layer is about 5 nm to about 20 nm.

20. An electronic device comprising:
the sensor of claim 15.
